(19) United States
(12) Patent Application Publication
(10) Pub. No.: US 2026/0155331 A1
(43) Pub. Date: Jun. 4, 2026

(54) SYSTEMS AND METHODS FOR ELECTRON MICROSCOPY IMAGING

(71) Applicant: FEI COMPANY, Hillsboro, OR (US)

(72) Inventors: Radek Jancík, Brno (CZ); Ron Kelley, Portland, OR (US); Jiri Vítecek, Boleradice (CZ); Bronislav Pribyl, Brno (CZ); Daniela Slamkova, Brno (CZ); Milos Hovorka, Brno (CZ); Ondrej Machek, Hradec Kralove (CZ)

(21) Appl. No.: 19/404,809

(22) Filed: Dec. 1, 2025

Related U.S. Application Data
(60) Provisional application No. 63/726,415, filed on Nov. 29, 2024.

(51) Int. Cl. H01J 37/26; H01J 37/21

(52) U.S. Cl. CPC H01J 37/26; H01J 37/21; H01J 2237/216; H01J 2237/221

(57) ABSTRACT

There is provided systems and methods for electron microscopy imaging, including a method for imaging a sample using a charged particle microscope, the method comprising: acquiring an initial image of a surface of the sample using the charged particle microscope; receiving an indication of one or more initial areas of interest for one or more auto-functions for the charged particle microscope; acquiring a series of subsequent images of subsequent surfaces of the sample using the charged particle microscope. Wherein, for each subsequent image, acquiring said subsequent image comprises exposing the respective subsequent surface of the sample; identifying, one or more areas of interest corresponding to the one or more initial areas of interest; and imaging the respective subsequent surface wherein imaging the respective subsequent surface comprises applying the one or more auto-functions based on at least one of the identified areas of interest corresponding to the one or more initial areas of interest.

### CROSS-REFERENCE TO RELATED APPLICATIONS

This application claims the benefit of U.S. provisional application no. 63/726,415 filed Nov. 29, 2024, which disclosure is herein incorporated by reference in its entirety.

### FIELD OF THE INVENTION

The present invention relates to identifying areas of interest for the imaging of samples using charged particle microscopy. In particular, methods and systems are presented for identifying areas of interest through slices of a sample for use with autofunctions.

### BACKGROUND

Charged particle microscopy is a technique well-known for imaging microscopic objects. Charged particle microscopy refers to the use of beams of charged particles to illuminate samples for imaging. Typically, the charged particles used are electrons which provides significantly increased image resolution compared with visible light microscopy. Examples of charged particle microscope devices include devices such as Scanning Electron Microscopes (SEM), Focused Ion Beam Scanning Electron Microscopes (FIB-SEM), Transmission Electron Microscopes (TEM), Scanning Transmission Electron Microscopes (STEM).

In order to acquire correctly resolved images of a given sample, various parameters of a charged particle microscope need to be set (or adjusted). Such parameters include lens alignment, eucentric height, focus, astigmatism, focus centering, beam centering, contrast, brightness and so on. Automatic functions (known as autofunctions) have been developed to allow automatic adjustment of such parameters. Such functions are typically applied to a portion of a sample surface (or portion of an image of a sample) to determine one or more suitable parameter value. These autofunctions (AF) may include but are not limited to a lens aligning function, a stigmator function, a focus function, a contrast/brightness function, a focus centering function, and/or a stigmator centering function. One of the many autofunctions is the autofocus function which is particularly important for charged particle microscopy and unsupervised imaging. One way of autofocusing is by using a laser, where the laser is used to measure the distance to the sample surface. An offset is used from the surface to the actual focal point of the sample to set the focus. Another way to autofocus is image based autofocus. Image-based autofocus relies on measuring, and maximising image sharpness at various focus positions within an expected range. Since the intensity difference between adjacent pixels naturally increases with correct image focus, the optical system can thereby be adjusted until the maximal sharpness is detected.

It will also be appreciated that various sample types, such as biological samples (such as frozen cells on a grid, high pressure frozen samples, resin embedded samples, etc.), semiconductor samples, material samples or any other samples that may be studied under charged particle microscopy can be sensitive to radiation damage. Such damage may degrade the sample during imaging. In some cases, the sample may exhibit charging when subjected to imaging by electron microscopy, leading to lower image quality throughout long term data collection. Not all parts of the sample may be susceptible to radiation damage and charging. However, even the sensitivity of some parts of the samples leads to lowering of image quality throughout long term data collection. To avoid this typically users manually adjust the charged particle microscope to perform the autofunctions on relevant parts of the sample which are outside of the desired imaging area to avoid radiation damage. However, manual adjustment of areas upon which to perform autofunctions may be time consuming when collecting data from highly sensitive samples.

Additionally, where the imaging of one or more areas of interest (for example a specific cell, selected region of a tissue, organelle, cell wall, etc.) may be the goal, the sample may be studied in slices. This allows for the imaging of, for example, the 3D structure of the area of interest. For samples with well-defined flat surface, the location for an autofunction would be determined based on the geometry of the stage, the beams and the sample surface. However, since the geometry of the feature of the interest may be curved, said feature may therefore not be in the same area in every slice of the sample. In such cases conventional imaging methods using autofunctions may fail. Once again, the user may manually adjust the charged particle microscope for every slice but manual adjustment can be time consuming.

### SUMMARY OF INVENTION

It is an object of the present invention to address the above problems with the application of autofunctions during imaging. In particular, the present invention uses machine learning techniques and/or image processing techniques to select suitable areas of interest to apply autofunctions. As such, human intervention to set autofunction areas may be eliminated whilst maintaining image quality. The present invention is particularly advantageous when imaging multiple slices (or surfaces) of a sample with unknown internal geometry. Here autofunctions may be executed without the unnecessary intervention of a user throughout the data collection process. We note that the terms slices and surfaces are used interchangeably throughout.

Although the above discussion relates to biological samples, the same applies to any type of sample that may be studied under a charged particle microscope. As such, it will be understood that the invention is not limited to data collection for biological samples and may be applied to data collection for semi-conductor samples, materials science samples, etc.

Methods and systems are described herein which can be used to easily track and find similar areas of interest where autofunctions should be executed for imaging using electron microscopy.

In a first aspect there is a provided a method for imaging a sample using a charged particle microscope. The method comprises acquiring an initial image of a surface of the sample using the charged particle microscope; receiving an indication of one or more initial areas of interest for one or more auto-functions for the charged particle microscope; acquiring a series of subsequent images of subsequent surfaces of the sample using the charged particle microscope. Wherein, for each subsequent image, acquiring said subsequent image comprises exposing the respective subsequent surface of the sample; identifying, one or more areas of interest corresponding to the one or more initial areas of interest; and imaging the respective subsequent surface wherein imaging the respective subsequent surface comprises applying the one or more auto-functions based on at least one of the identified areas of interest corresponding to the one or more initial areas of interest. Receiving an indication of an initial area may comprise (or be equivalent to) receiving an annotation by a user indicating the initial area of interest. The sample for imaging may be a 2D or a 3D sample. For example, the sample may be a 2D or 3D biological sample prepared by cryogenic freezing, a 2D or 3D biological sample embedded in resin, a 2D or 3D material science sample, or a 2D or 3D semiconductor sample. As used herein, 2D encompasses samples that are of a 2D nature, i.e. samples that are not explicitly 2D but have some 2D characteristics, such as a wafer with thin sections of resin embedded sample.

Exposing the respective subsequent surface of the sample may be done by using focused ion or electron beam milling, a laser or a diamond blade to expose each subsequent surface.

Examples of suitable autofunctions include any one or more of a lens aligning function, a stigmator function, a focus function, a contrast/brightness function, a focus centering function, a stigmator centering function, and so on.

In some embodiments identifying one or more surface areas of interest corresponding to the one or more initial areas of interest comprises: identifying in a previous image (or image of a previous surface) ne or more areas of interest corresponding to the one or more initial areas of interest: and imaging the respective subsequent surface wherein imaging the respective subsequent surface comprises applying the one or more auto-functions based on at least one of the identified areas of interest of the previous image.

Alternatively, identifying one or more surface areas of interest corresponding to the one or more initial areas of interest may comprise: imaging the surface; identifying one or more areas of interest corresponding to the one or more initial areas of interest; and imaging (or re-imaging) the surface. Here imaging (or re-imaging) the respective subsequent surface may comprise applying the one or more auto-functions to at least one of the identified areas of interest.

In some embodiments the method further comprises: calculating similarity scores between the one or more initial areas of interest of the initial image and a plurality of sub-areas of the image of the respective subsequent surface of the sample; and selecting one or more sub-areas as candidate areas of interest in the respective subsequent surface of the sample based on the respective similarity scores (such as cross correlations or cosine similarities etc.). The method may further comprise: computing reference encodings of the one or more initial areas of interest of the initial image; computing encodings of the plurality of sub-areas of the image of the respective subsequent surface of the sample. Here the similarity score for each pair of initial areas of interest and sub-areas of interest is a similarity score between the respective encodings.

The reference encoding may be a deep embedding calculated by the trained machine learning algorithm (or model), such as a vision transformer neural network, and the encodings of the plurality of sub-areas are deep embeddings of the plurality of sub-areas calculated by the trained machine learning model.

In some embodiments the reference encodings and encodings of the sub-areas may be respective image histograms with the similarity score a Kullback-Leibler divergence between respective histograms. In some embodiments the reference encodings and encodings of the sub-areas are generated by Gabor filters.

In some embodiments the selecting areas of interest from the candidate areas of interest is based one or more selection criteria. The selection criteria may comprise one or more of: a distance metric to the initial area of interest; exclusions areas (or zones) on the surface; a distance metric to the centre of the field of view.

In some embodiments the step of identifying one or more areas of interest uses a trained machine learning model (such as a Video Object Segmentation Model), wherein the one or more initial area of interest defines one or more features of interest. Here said identifying comprises tracking, using the trained machine learning model, the one or more features of interest through the previous images of the series. The trained machine learning model may be arranged to segment each of the subsequent images using the initial area of interest as a reference segmentation of the feature of interest.

The invention also provides apparatus corresponding to, and comprising elements, modules or components arranged to put into effect the above methods, for example one or more various suitably configured computing devices such as those described below.

In particular the invention therefore provides a system for imaging a sample using a charged particle microscope. The system comprises one or more processors and a memory having stored thereon instructions which when executed by the system cause the system to: acquire using the charged particle microscope (or receive therefrom) an initial image of a surface of the sample; receive an indication of one or more initial areas of interest for one or more auto-functions for the charged particle microscope; acquire using the charged particle microscope (or receive therefrom) a series of subsequent images of subsequent surfaces of the sample. Wherein, for each subsequent image, acquiring said subsequent image comprises exposing the respective subsequent surface of the sample; identifying, one or more areas of interest corresponding to the one or more initial areas of interest; and imaging the respective subsequent surface wherein imaging the respective subsequent surface comprises applying the one or more auto-functions based on at least one of the identified areas of interest corresponding to the one or more initial areas of interest. As such the system may also comprise the charged particle microscope, or alternatively be separate from, and communicably connected to the charged particle microscope.

The invention also provides one or more computer programs suitable for execution by one or more processors, such computer program(s) being arranged to put into effect the methods outlined above and described herein. The invention also provides one or more computer readable media, and/or data signals carried over a network, which comprise (or store thereon) such one or more computer programs.

### BRIEF DESCRIPTION OF THE DRAWINGS

Embodiments of the invention will now be described, by way of example only, with reference to the accompanying drawings, in which:

FIG. 1 schematically illustrates an example scenario in which a sample is analysed using a charged particle microscopy arrangement;

FIG. 2 schematically illustrates an example of a computer system which may be used in the invention;

FIG. 3A schematically illustrates the failure of autofunctions through different surfaces when attempting to identify area(s) similar to the initial area(s) of interest;

FIG. 3B schematically illustrates the failure of autofunctions functions through different surfaces when attempting to identify/track the area of interest through different surfaces;

FIG. 4a schematically illustrates an example of a system in which a sample surface is imaged;

FIG. 4B schematically illustrates an example embodiment of the system of the area of interest module 4300;

FIG. 4C schematically illustrates an example embodiment of the system of the area of interest module 4300;

FIG. 5 is a flowchart illustrating a method 500 for imaging a subsequent sample surface;

FIG. 6A is a flowchart illustrating a method 610 for acquiring an image of the subsequent surface;

FIG. 6B is a flowchart illustrating a method 620 for acquiring an image of the subsequent surface;

FIG. 7A illustrates identification of similar areas of interest in a subsequent sample given an initial area of interest;

FIG. 7B illustrates identification (or tracking) of an area of interest in a subsequent sample given an initial area of interest.

### DETAILED DESCRIPTION OF THE EMBODIMENTS OF THE INVENTION

In the description that follows, and in the figures, certain embodiments of the invention are described. However, it will be appreciated that the invention is not limited to the embodiments that are described and that some embodiments may not include all of the features that are described below. It will be evident, however, that various modifications and changes may be made herein without departing from the broader spirit and scope of the invention as set forth in the appended claims.

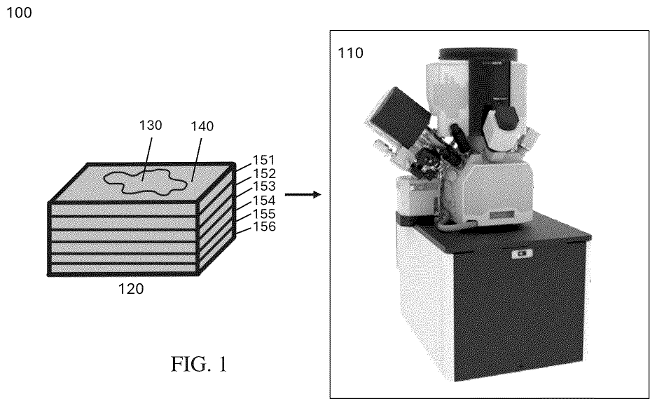

FIG. 1 schematically illustrates an example system 100 in which a sample 120 is analysed using a charged particle microscope arrangement 110 (or charged particle microscope). The charged particle microscope arrangement 110 may be a SEM, FIB-SEM, STEM, TEM, and so on. The sample 120 may be for example a biological sample with the feature of interest 130 for which images are required.

The sample 120 may be for example a biological sample. The sample 120 has the feature of interest 130. The sample may have multiple features of interest 130. The feature of interest 130 in the sample 120 is typically what the user desires to be imaged throughout the subsequent slices of the sample. To do so, the user selects an area of interest to include the feature of interest. The autofunction area (i.e. the area to which the autofunctions may be applied) can be defined in relation to the area of interest. Typically, the autofunction area is defined to be outside of the area of interest to avoid causing radiation damage to the area of interest when performing the autofunctions. In particular the autofunction area may be defined based on a constant offset (such as a pixel offset) from the area of interest. The area of interest will typically be tracked or identified by using machine learning techniques through subsequent slices of the sample 120. The area of interest is based on the feature of interest, i.e. the area of interest is selected to include all or at least a portion of the feature of interest 130. This charged particle microscope arrangement 110 applies one or more autofunctions to the autofunction area defined in relation to the area of interest to then configure the charged particle microscope 110 based on output of the functions, i.e. the imaging parameters generated by said autofunctions. The charged particle microscope arrangement then images the area of interest on sample slice using the parameters generated by the application of the autofunctions. Typically, the whole sample slice is imaged by the charged particle microscope arrangement, in this way including the area of interest. However, it will be appreciated that only a portion of the surface including the area of interest may be imaged.

The feature of interest 130 may have an unknown geometry. The sample 120 may be sliced by systems external to the charged particle microscope arrangement 110 or systems internal to it. The sample may be sliced up into many slices 151; 152; 153; . . . ; 156 and each slice (or surface) may be imaged by the charged particle microscope arrangement 110 separately (or individually).

The charged particle microscope arrangement 110 is arranged to receive the sample 120. The charged particle microscope arrangement 110 may be arranged to slice the sample using for example a diamond knife, ion beam or a laser.

The sample 120 may be prepared using various techniques in the art of charged particle microscopy which are well known to the skilled person.

The sample 120 for imaging may be any one or more of: a 2D or 3D biological sample prepared by cryogenic freezing, a 2D or 3D biological sample embedded in resin, a 2D or 3D material science sample, or a 2D or 3D semiconductor sample, or a sample prepared by one or more various techniques already known in the art of charged particle microscopy. Such preparation techniques are not discussed further herein.

In use the charged particle microscope arrangement 110 is used to image the first (or initial) surface of the sample 120. As part of the imaging of the surface of the sample 120 the charged particle microscope arrangement 110 carries out (or performs) one or more functions to set various imaging parameters of the charged particle microscope arrangement 110. In this way the resulting image of the surface of the sample 120 is an image acquired using the values of the various imaging parameters set by the one or more functions (or autofunctions). It will be appreciated that as well as using imaging parameters set by the one or more autofunctions the image acquisition may also use other imaging parameters set by the user (or predefined based on standard values). These autofunctions may include but are not limited to any one or more of: a lens aligning function, a stigmator function, a focus function, a contrast/brightness function, a focus centering function, a stigmator centering function, and so on.

The autofunctions enable the charged particle microscope to automatically adjust parameters such as lens alignment, eucentric height, focus, astigmatism, centring, contrast, brightness and so on.

In order to ensure that the feature of interest 130 in the surface of the sample 110 is correctly (or reliably or accurately) imaged the one or more functions are applied to an autofunction area defined in relation to the area of interest on the surface of the sample. The area of interest is selected to include at least a portion of the feature of interest 130. The relationship between the autofunction area and the area of interest is defined to ensure the autofunctions area is representative of the area of interest. In this way it is ensured that the feature of interest in a given image is well resolved.

As set out above, subsequent surfaces of the sample 120 (or surfaces of subsequent slices of the sample 110) are exposed by slicing the sample 120. As each subsequent surface of the sample is exposed said subsequent surface is imaged using the charged particle microscope arrangement 110. Such imaging is carried out in the same manner as the imaging of the initial surface set out above. In particular, the charged particle microscope arrangement 110 carries out (or performs) one or more functions to set various imaging parameters of the charged particle microscope arrangement 110, on the autofunction area defined in relation to an area of interest of the subsequent surface. Again, such areas of interest are based on the feature of interest, i.e. ideally selected to include all or at least a portion of the feature of interest 130 in the surface.

In this way it will be appreciated that a given feature of interest in a sample, which may appear in multiple slices of the sample, is correctly imaged across all slices in which it appears.

Whilst the above discussion is presented in terms of each surface being subsequent surfaces of a sliced 3D sample, it will also be appreciated that this also applies to a sequence of surfaces of different samples all comprising a common feature of interest that may be 2D or 3D (such as a specific organelle type to be imaged in different cell samples).

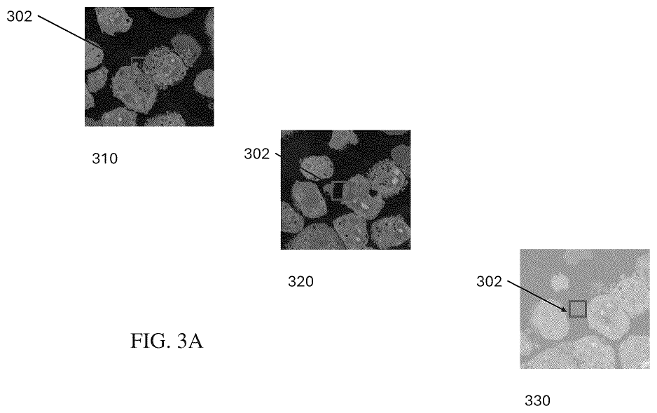

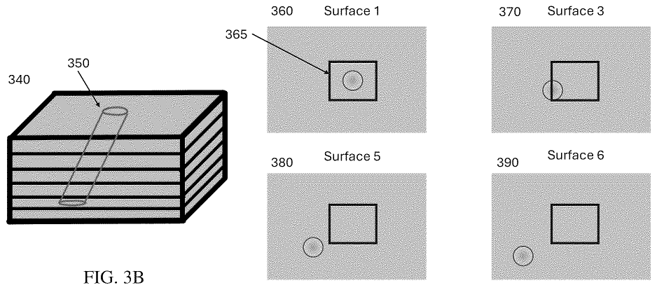

The consequences of the areas of interest for subsequent surfaces failing to be based on the feature of interest 130, is discussed shortly below in relation to FIGS. 3A and 3B.

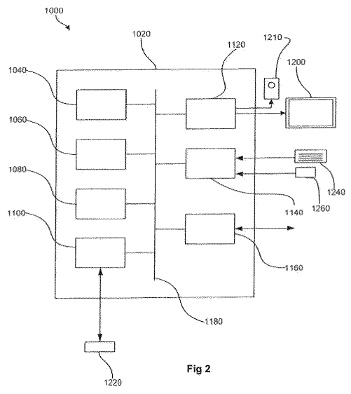

FIG. 2 schematically illustrates an example of a computer system 1000 that may be used in embodiments of the invention. The system 1000 comprises a computer 1020. The computer 1020 comprises: a storage medium 1040, a memory 1060, a processor 1080, an interface 1100, a user output interface 1120, a user input interface 1140 and a network interface 1160, which are all linked together over one or more communication buses 1180. The charged particle microscope arrangement 110 may have computer system 1000 in built or may have the computer system 1000 external to it. If the computer system is external to the charged particle microscope arrangement 110, they may be connected via a network interface or other suitable data connection means.

The storage medium 1040 may be any form of non-volatile data storage device such as one or more of a hard disk drive, a magnetic disc, an optical disc, a ROM, etc. The storage medium 1040 may store an operating system for the processor 1080 to execute in order for the computer 1020 to function. The storage medium 1040 may also store one or more computer programs (or software or instructions or code).

The memory 1060 may be any random-access memory (storage unit or volatile storage medium) suitable for storing data and/or computer programs (or software or instructions or code).

The processor 1080 may be any data processing unit suitable for executing one or more computer programs (such as those stored on the storage medium 1040 and/or in the memory 1060), some of which may be computer programs according to embodiments of the invention or computer programs that, when executed by the processor 1080, cause the processor 1080 to carry out a method according to an embodiment of the invention and configure the system 1000 to be a system according to an embodiment of the invention. The processor 1080 may comprise a single data processing unit or multiple data processing units operating in parallel or in cooperation with each other. The processor 1080, in carrying out data processing operations for embodiments of the invention, may store data to and/or read data from the storage medium 1040 and/or the memory 1060. The processor 1080 may comprise one or more graphics processing units (GPUs) operating in cooperation with other data processing units of the processor 1080.

The interface 1100 may be any unit for providing an interface to a device 1220 external to, or removable from, the computer 1020. The device 1220 may be a data storage device, for example, one or more of an optical disc, a magnetic disc, a solid-state-storage device, etc. The device 1220 may have processing capabilities—for example, the device may be a smart card. The interface 1100 may therefore access data from, or provide data to, or interface with, the device 1220 in accordance with one or more commands that it receives from the processor 1080.

The user input interface 1140 is arranged to receive input from a user, or operator, of the system 1000. The user may provide this input via one or more input devices of the system 1000, such as a mouse (or other pointing device) 1260 and/or a keyboard 1240, that are connected to, or in communication with, the user input interface 1140. However, it will be appreciated that the user may provide input to the computer 1020 via one or more additional or alternative input devices (such as a touch screen). The computer 1020 may store the input received from the input devices via the user input interface 1140 in the memory 1060 for the processor 1080 to subsequently access and process, or may pass it straight to the processor 1080, so that the processor 1080 can respond to the user input accordingly.

The user output interface 1120 is arranged to provide a graphical/visual and/or audio output to a user, or operator, of the system 1000. As such, the processor 1080 may be arranged to instruct the user output interface 1120 to form an image/video signal representing a desired graphical output, and to provide this signal to a monitor (or screen or display unit) 1200 of the system 1000 that is connected to the user output interface 1120. Additionally, or alternatively, the processor 1080 may be arranged to instruct the user output interface 1120 to form an audio signal representing a desired audio output, and to provide this signal to one or more speakers 1210 of the system 1000 that is connected to the user output interface 1120.

Finally, the network interface 1160 provides functionality for the computer 1020 to download data from and/or upload data to one or more data communication networks.

It will be appreciated that the architecture of the system 1000 illustrated in FIG. 2 and described above is merely exemplary and that other computer systems 1000 with different architectures (for example with fewer components than shown in FIG. 2 or with additional and/or alternative components than shown in FIG. 2) may be used in embodiments of the invention. As examples, the computer system 1000 could comprise one or more of: a personal computer; a server computer; a mobile telephone; a tablet; a laptop; other mobile devices or consumer electronics devices; distributed (or cloud) computing systems etc.

FIG. 3A schematically illustrates the failure of autofunctions through different surfaces when attempting to identify area(s) similar to the initial area(s) of interest. For example, the user annotates the initial surface 310 with the initial area of interest on which to apply the one or more autofunctions. The user has selected to study the cell wall and has annotated on the initial surface 310 an area of interest 302. As such, the cell wall is the feature of interest 130 in this example. On a subsequent surface 320, the user's initial annotation of the area of interest 302 is still near the feature of interest but no longer directly above it due to the uneven and curved 3D structure of the cells. On a subsequent surface 330, the user's initial annotation is no longer near the feature of interest as the surface of each slice changes due to the uneven and curved 3D structure of the cells.

For the surface 320 as the feature of interest 130 is still near the initial area of interest 302. This initial area of interest can be used to define the autofunction area to apply the autofunctions when imaging the surface 320. The resulting image of the surface 320 should still be correctly resolved with respect to the feature of interest, and as such, the resulting image should correctly (or accurately) depict the feature of interest. However, for surface 330 the initial area of interest is not near the feature of interest 304. As such, if this initial area of interest is used to define the autofunction area to apply the autofunctions when imaging the surface 330 the resulting image will not correctly depict the feature of interest. For example, the feature of interest may be out of focus, or there may not be sufficient contrast to make out the feature of interest. This is because the autofunction (or autofunctions) setting the parameters which determine such properties will not be taking into account the feature of interest 130, as it is not near the area to which the autofunction (or autofunctions) are applied.

Similarly FIG. 3B schematically illustrates the failure of autofunctions through different surfaces when attempting to identify/track an feature of interest through different slices (the area of interest through different surfaces). For example, an object 350 needs to be imaged in sample 340. The user annotates the area of interest 365 on the image of the first sample surface 360 that is to be tracked throughout the subsequent surfaces so that the one or more autofunctions may be applied to an autofunction area defined in relation to the tracked are of interest. However, as the 3D structure of the feature of interest 350 is not known and unevenly distributed in the cell, the placement of the autofunctions based on the initial user annotation will fail in the subsequent surfaces 370, 380, 390.

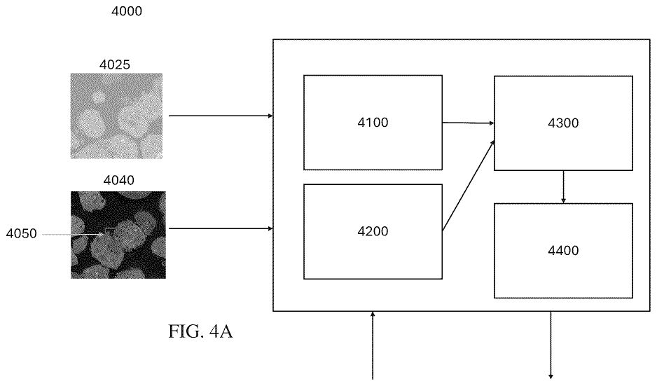

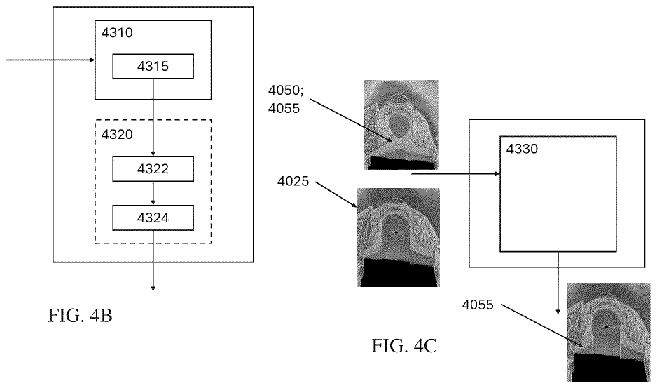

FIG. 4A schematically illustrates an example of a system by which a sample 120 surface is imaged. The system 4000 comprises various modules which are arranged to send and receive an input and output respectively to each other. The system 4000 comprises a receiving module 4100, an indication module 4200, and an area of interest module 4300. The system may optionally comprise a autofunction area module 4400. The system 4000 may be part of the charged particle microscope 110 or may be a separate external system connected to the charged particle microscope 110.

The receiving module 4100 is arranged to receive a sample surface image 4025. The sample surface image 4025 received by the receiving module 4100 may be an image of a sample surface that is to be reimaged or may be an image of the sample surface prior to the sample surface that is to be imaged.

The receiving module 4100 may be arranged to receive the sample surface image 4025 from the charged particle microscope 110 directly, for example wherein the system 4000 is part of the charged particle microscope 110 and the receiving module 4100 is concerned with acquisition of sample surface images. The receiving module 4100 may be arranged to receive the input of the sample surface image 4025 indirectly from the charged particle microscope, for example, from the memory of the charged particle microscope 110, via a communication network between the system 4000 and the charged particle microscope 110. It will be appreciated that the receiving module 4100 may be arranged to receive the input of the sample surface image 4025 from a suitable external system.

The indication module 4200 is arranged to receive one or more initial areas of interest 4050 for a surface of a sample 120. The one or more initial areas of interest may be on an initial surface (or slice) of the sample. However, it will be appreciated that the one or more initial areas of interest need not always be on the initial surface since the area of interest may not yet be visible and might only be visible at a later surface. The indication module 4200 may be arranged to receive the one or more initial areas of interest 4050 from a user. The user may annotate (or indicate on) an image of the initial surface of a sample 120 one or more areas of interest. An area of interest is typically chosen by the user to include all or part of a feature of interest 130 as described previously. The feature of interest is one which the user desires to be tracked (or identified) through subsequent sample surfaces. Alternatively, the indication module 4200 may be arranged to receive the one or more initial areas of interest 4050 from an external/another system configured to generate one or more initial areas of interest.

The area of interest module 4300 is arranged to identify one or more areas of interest corresponding to the one or more initial areas of interest. The one or more areas of interest identified are for a given surface of the sample 130. The initial areas of interest may be the areas of interest received by the indication module 4200. Alternatively, the initial areas of interest may be areas of interest previously identified by the area of interest module 4300 for a preceding surface of the sample 130.

It will be appreciated that the identified one or more areas of interest correspond to the one or more initial areas of interest such that the identified areas of interest comprise features of interest (or portions thereof) in common with the initial areas of interest, with respect to their respective surfaces of the sample 130. Here the same feature of interest may mean the same physical entity. For example, where the respective slices comprise slices of the same organelle the identified one or more areas of interest correspond to the one or more initial areas of interest both include portions of said organelle. Alternatively in some embodiments the same feature of interest may mean different physical entities of the same type. For example, where the respective slices comprise slices of the different organelles of the same type the identified one or more areas of interest correspond to the one or more initial areas of interest include portions of their respective organelles.

The area of interest module 4300 may be arranged to output the one or more identified areas of interest for later acquisition of an image of the given surface. Alternatively, the area of interest module 4300 may be arranged to trigger (or instruct or otherwise cause) the imaging of the sample, using the one or more areas of interest to define the autofunction area to apply autofunctions used in said imaging. Said imaging comprises applying the one or more autofunctions to an autofunction area defined in relation to at least one of the identified areas of interest and acquiring an image using the charged particle microscope 110 based on the output of the functions. It will be appreciated that the system 4000 may be arranged to apply the functions to the identified one or more areas of interest and configure the charged particle microscope 110 based on the parameters generated by said autofunctions.

As discussed above the autofunctions may be carried out on the area of interest itself. However, more typically, the autofunctions will be carried out on an autofunction area defined in relation to the area of interest. As such, the system 4000 may comprise the autofunction area module 4400. The autofunction area model is arranged to define an autofunction area based on the area of interest output by the area of interest module 4300. The autofunction area module 4400 may store one or more pre-defined relative autofunction area definitions specifying the relative positions and/or extent of the autofunction area with respect to an area of interest. Examples of such relative definitions include a vector offset form the area of interest.

A further discussion of the area of interest module 4300 and its alternative embodiments is given below.

FIG. 4B schematically illustrates an example embodiment of the system of the area of interest module 4300. In the example embodiment of FIG. 4B, the area of interest module 4300 comprises a machine learning (ML) model 4310 and a processing module 4320. The processing module 4320 comprises a cosine similarity module 4322 and a filtering module 4324.

The ML model 4310 comprises an encoder 4315. The encoder 4315 of the ML model 4310 is configured to calculate deep embeddings of the input received by the ML model 4310. The ML model 4310 receives inputs of the sample surface image 4025 and one or more initial areas of interest 4050. Deep embeddings are mathematical representations of data, the data in this case being the inputs of the sample surface image 4025 and one or more initial areas of interest 4050. As such it will be appreciated that deep embeddings are a particular type of data encoding (or encoding) of input data.

The ML model 4310 may be a multi-layer neural network that encodes any image into a deep embedding space of vectors.

The ML model 4310 may be (but not limited to), a convolutional neural network or a vision transformer neural network. The ML model 4310 may be trained on public data sets. The ML model may also be trained on general, not domain-specific images, such as consumer-camera photographs. The encoder 4315 of the ML model 4310 typically computes a respective deep embedding for each sub area of the input image it receives. Typically, the sub-areas are square arrays of pixels (a common size being 16×16 pixels). However, it will be appreciated this is merely an example of a sub-area and the ML model is not limited to 16×16 pixel blocks.

The encoder 4315 of the ML model 4310 receives one or more initial areas of interest 4050 and calculates and stores reference deep embeddings of the one or more initial areas of interest 4050. The one or more initial areas of interest 4050, as previously discussed, may include all or part of a feature of interest 130 on an initial surface of a sample 120. The reference deep embeddings of the one or more initial areas of interest 4050 may be stored in the ML model 4310 or in an external memory connected to the ML model 4310 via a suitable communications network (not shown in FIG. 4B).

The encoder 4315 of the ML model 4310 then receives the sample surface image 4025 on which similar areas of interest are to be identified. The encoder 4315 of the ML model 4310 calculates and stores deep embeddings of the sample surface image 4025. The deep embeddings of the sample surface image 4025 may be stored in the ML model 4310 or in an external memory connected to the ML model 4310 via a suitable communications network (not shown in FIG. 4B).

The processing module 4320 comprises a similarity module 4322 and a filtering module 4324. The calculated reference deep embeddings and deep embeddings are inputted into the similarity module 4322 from the ML model 4310 directly. Alternatively, the reference deep embeddings and deep embeddings are inputted into the similarity module 4322 from the external memory connected that is connected to the ML model 4310 via a suitable communications network (not shown in FIG. 4B).

The similarity 4322 module is configured to determine a set of candidate areas of interest from the sample surface image 4025. Typically, such candidate areas of interest are determined based on a similarity (or similarity score) deep embedding of the proposed area of interest and the embedding of one or more initial areas of interest meeting a pre-defined criteria. The pre-defined criteria can include any of: a pre-defined threshold (e.g. any candidate area having a similarity exceeding the threshold), a rank criteria (e.g. selecting the candidate areas having the highest similarity scores), etc.

Typically, the similarity module uses cosine similarity. In this way the similarity 4322 module may be arranged to calculate cosine similarities between the reference deep embeddings of the one or more initial areas of interest 4050 and the deep embeddings of the candidate areas of interest. It will be appreciated that other similarity scores may be used.

The candidate areas of interest are then typically inputted into the filtering module 4324 which applies one or more filtering criteria to reduce the number of candidate areas of interest. The filtering module 4324 outputs the remaining areas of interest to determine the autofunction areas on which autofunctions may be applied. The autofunctions applied may be one or more of the autofunctions listed in relation to FIG. 1.

The filtering module 4324 filters the generated candidate areas to output areas of interest. The filtering module 4324 may apply one or more of the following criteria to filter out the candidate areas of interest to generate the areas of interest: a distance metric to the initial area of interest; exclusions areas (zones) on the surface; a distance metric to the centre of the field of view, etc.

It will be appreciated that the filtering module may be omitted entirely. For example, the similarity module mya be arranged to output a single area of interest, such as the candidate area of interest with the highest similarity score.

The ML model 4310 discussed above may be comprised of any one or more of a number of well-known ML algorithms. In a particular example, the Vision Transformer ML model may be used. Full details of the Vision Transformer model may be found in “An Image Is Worth 16×16 Words: Transformers For Image Recognition At Scale”, Alexey Dosovitskiy et al., arXiv:2010.11929, https://doi.org/10.48550/arXiv.2010.11929. In this example, the trained encoder of the Vision Transformer model is used as the encoder 4315. The trained encoder computes deep embeddings of an input image, such that for each 16×16 pixels area in the image, there is one such embedding. The centres of reference of the one or more initial areas of interest 4050 are calculated and stored as reference embeddings. Deep embeddings of the sample surface 4025 are calculated. The deep embeddings are compared to the reference embeddings using cosine similarity metric. The most similar deep embeddings are chosen and mapped to coordinates in the sample surface image 4025 to compute similarity.

In this way the area of interest module 4300 of FIG. 4B will be understood to identify areas of interest in subsequent surfaces that are similar to the initial area of interest. In particular, the identified areas of interest may not track a particular physical entity (such as a specific organelle) through the sequence of surfaces. However, the identified areas of interest identified include features of interest of the same or similar type to features of interest in the initial area.

Whilst in the above discussion a machine learning model is used it will be appreciated that the above approach may alternatively be implemented using classical image processing techniques. In particular, the machine learning model 4310 and similarity module 4322 may be replaced with a single image processing similarity module. The image processing similarity module may receive as input the sample surface image 4025 and one or more initial areas of interest 4050. The image processing similarity module may then determine the candidate areas of interest using known methods of image comparison.

Such methods of image comparison may include any of:
Cross-correlation—where the cross correlation of an initial area of interest 4050 and a candidate area of interest defines the similarity score between the initial area of interest 4050 and a candidate area of interest;
Histogram comparison—where respective image histograms are calculated for an initial area of interest 4050 and a candidate area of interest. The Kullback-Leibler divergence between the respective histograms may then define the similarity score between the initial area of interest 4050 and a candidate area of interest; or
Gabor filter similarity—where a respective encoding is calculated for an initial area of interest 4050 and a candidate area of interest. These encodings may in effect stand in for the deep embeddings described above. As such the similarity score between the initial area of interest 4050 and a candidate area of interest may be defined as the cosine similarity between the respective Gabor filter encodings.

FIG. 4C schematically illustrates an example embodiment of the system of the area of interest module 4300. In the example embodiment of FIG. 4C, the area of interest module 4300 comprises a ML segmentation model 4330.

The ML model 4330 is arranged to receive an input of one or more initial areas of interest 4050 based on one or more features of interest 4055. In this case the initial area of interest 4050 typically specifies the corresponding feature of interest 4055. As such the area of interest 4050 in this embodiment may be thought of as a segmentation mask, usually generated by the user. In the example image shown in FIG. 4C the area of interest 4050 and feature of interest 4055 is shown in yellow. The ML model 4330 is also arranged to receive the sample surface image 4025 on which the area of interest 4050 is to be tracked.

The ML model is arranged to track the initial area of interest 4050 through the sample surface image 4025. It may be understood that such tracking is analogous to tracking an object through subsequent frames of a video. In particular the initial area of interest may be seen as segmenting (or identifying the object (in this case the feature of interest) to be tracked. The initial area of interest may be thought of as the reference segmentation and the image corresponding to the initial area of interest the reference frame. The ML model 4330 is arranged to generate an area of interest on the sample surface image 4025 corresponding to (or defining or including) the feature of interest 4055 of the initial area of interest. Typically, the output area of interest is in the form of a segmentation map (or mask) for the feature of interest.

As with the examples discussed above the output area of interest may be used to perform autofunctions for image acquisition. In particular the output area of interest may be used to define an autofunction area on which the autofunctions described previously may be performed.

It will be understood that any suitable video or image segmentation model (such as any Video Object Segmentation model) may be used as the ML model 4330. Examples of such models are discussed in Gao, M., Zheng, F., Yu, J. J. Q. et al. Deep learning for video object segmentation: a review. Artif Intell Rev 56, 457-531 (2023). https://doi.org/10.1007/s10462-022-10176-7.

A particularly advantageous ML model has been found by the inventors to be the Adaptive Feature Bank and Uncertain-Region Refinement (AFB-URR) model. Details of this model may be found in: Yongqing Liang, Xin Li, Navid Jafari, and Qin Chen. 2020. Video object segmentation with adaptive feature bank and uncertain-region refinement. In Proceedings of the 34th International Conference on Neural Information Processing Systems (NIPS '20). Curran Associates Inc., Red Hook, NY, USA, Article 289, 3430-3441. When using such a model the initial area of interest takes the place of the reference segmentation and the image corresponding to the initial area of interest the reference frame. The sample surface image 4025 takes the place of the target frame.

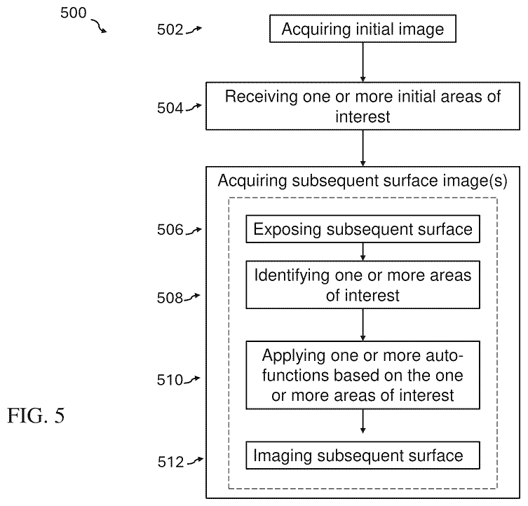

FIG. 5 is a flowchart illustrating a method 500 for imaging a subsequent sample surface (surface N) that may be performed by the system 100 of FIG. 1 and system 4000 of FIG. 4A according to some embodiments of the invention.

At a step 502, an initial image of surface is acquired using the charged particle microscope 110 according to the system 100.

At a step 504, an indication of one or more initial areas of interest, based on one or more features of interest, is received (by the indication module according to system 4000 of FIG. 4A).

At a step 506, the sample surface to be imaged is exposed to the charged particle microscope (which may be received by the receiving module according to the system 4000 of FIG. 4A).

At a step 508, one or more areas of interest to be imaged are identified by the system described in FIGS. 4B and 4C.

At a step 510 one or more autofunctions (as discussed with respect to FIG. 1) are applied based on the identified one or more areas of interest on the sample surface.

At a step 512, the sample surface is imaged by virtue of application of the autofunctions.

A further discussion of the various embodiments of FIG. 5 is given below.

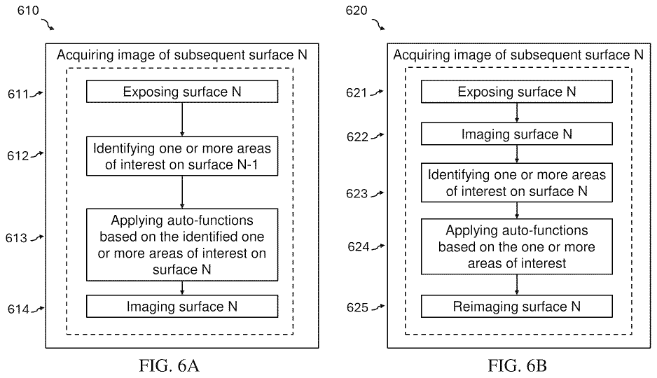

FIG. 6A is a flowchart illustrating a method 610 for acquiring an image of the subsequent surface N that may be performed by the system 100 of FIG. 1 and system 4000 of FIG. 4A according to some embodiments of the invention. It will be appreciated that in FIG. 6A, the areas of interest are actually identified in the image of a surface previously imaged (surface N−1). This identified area of interest is then used for application of autofunctions on the surface N since the drift of the area of interest from the surface previously imaged (surface N−1) to surface to be imaged (surface N) will be minimal. This method is useful when the sample surface is sensitive. This will be discussed further below. As mentioned previously the autofunctions may be applied to the areas of interest themselves or, more commonly, applied to an autofunction area defined in relation to the areas of interest.

FIG. 6B is a flowchart illustrating a method 620 for acquiring an image of the subsequent surface N that may be performed by the system 100 of FIG. 1 and system 4000 of FIG. 4A according to some embodiments of the invention. It will be appreciated that in FIG. 6B, surface N is imaged and then areas of interest are identified on the imaged surface N. The areas of interest of surface N are then reimaged once the autofunctions have been performed to obtain a better image. This method is useful when the sample is not susceptible to degradation upon imaging and reimaging. This will be discussed further below.

In some cases, a user may wish to identify similar areas of interest in subsequent samples given the initial one or more areas of interest. Example embodiments that may be performed by the system of FIGS. 4A and 4B according to the steps laid out in flow diagrams of FIGS. 5, 6A and 6B are discussed below.

In one embodiment, to image surface N, the receiving module 4100 receives an image of surface N−1 4025 and the indication module 4200 receives an indication of one or more initial areas of interest as input 4050. The one or more initial areas of interest 4050, as previously discussed, may include all or part of a feature of interest 130 on an initial surface of a sample 120. The image of surface N−1 4025 is the image of the surface before surface N which has already been imaged by one of the embodiments of this invention. The image of surface N−1 4025 is obtained by the receiving module 4100 as discussed in relation to FIG. 4A. The one or more initial areas of interest 4050 are inputted into the area of interest module 4300 wherein the encoder 4315 of the ML model 4310 calculates deep embeddings of the one or more initial areas of interest 4050 and outputs reference deep embeddings of the one or more initial areas of interest 4050. The ML model 4310 may be the ML model as indicated by FIG. 4B. The encoder 4315 of the ML model 4310 may calculate one or more reference deep embeddings for each 16×16 pixel area in the input of the one or more initial areas of interest 4050. The image of surface N−1 4025 is then inputted in the encoder 4315 of the ML model 4310 in the area of interest module 4300. The encoder 4315 of the ML model 4310 calculates

deep embeddings of the image of surface N−1 4025. The encoder 4315 of the ML model 4310 may calculate one or more deep embeddings for each 16×16 pixel area in the image of surface N−1 4025. The calculated reference deep embeddings and the deep embeddings are inputted into the cosine similarity module 4322 of the processing module 4320, wherein cosine similarities between the reference deep embeddings and the deep embeddings are calculated to identify candidate areas of interest. The candidate areas of interest are inputted into the filtering module 4324. The filtering module 4324 outputs areas of interest on which autofunctions may be used to image surface N. The filtering is performed in a manner discussed in relation to FIG. 4B. Said imaging comprises applying the one or more autofunctions based on at least one of the identified areas of interest and acquiring an image of the surface N using the charged particle microscope 110 based on the output of the autofunctions. It will be appreciated that the system 4000 may be arranged to apply the autofunctions and configure the charged particle microscope 110 based on the parameters generated by said autofunctions and image of the surface N. Similarly, once surface N is imaged, the image of the surface N may be used to image surface N+1. This embodiment is particularly useful when the sample surface that is to be imaged is sensitive and may be damaged by the charged particle microscope.

In one embodiment, to image surface N, the indication module 4200 receives an indication of one or more initial areas of interest as input 4050. The one or more initial areas of interest 4050, as previously discussed, may include all or part of a feature of interest 130 on an initial surface of a sample 120. The one or more initial areas of interest 4050 are inputted into the area of interest module 4300 wherein the encoder 4315 of the ML model 4310 calculates deep embeddings of one or more initial areas of interest 4050 and outputs reference deep embeddings of the one or more areas of interest 4050. The encoder 4315 of the ML model 4310 may calculate one or more reference deep embedding for each 16×16 pixel area in the input of the one or more initial areas of interest 4050. The ML model may the ML model 4310 as indicated by FIG. 4B. Surface N is imaged by the charged particle microscope 110 and inputted 4025 into the receiving module 4100. The image of surface N 4025 is then inputted in the encoder 4315 of the ML model 4310 in the area of interest module 4300. The encoder 4315 of the ML model 4310 calculates deep embeddings of the image of surface N 4025. The encoder 4315 of the ML model 4310 may calculate one or more deep embeddings for each 16×16 pixel area in the image of surface N 4025. The reference deep embeddings and the deep embeddings are inputted into the cosine similarity module 4322 of the processing module 4320, wherein cosine similarities between the reference deep embeddings and the deep embeddings are calculated. The calculated cosine similarities are inputted into the filtering module 4324. The filtering module 4324 outputs areas of interest based on which autofunctions may be used to image surface N. The filtering is performed in a manner discussed in relation to FIG. 4b. Said imaging comprises applying the one or more autofunctions and acquiring an image of the surface N using the charged particle microscope 110 based on the output of the autofunctions. It will be appreciated that the system 4000 may be arranged to apply the functions to the identified one or more areas of interest and configure the charged particle microscope 110 based on the parameters generated by said autofunctions. This embodiment is particularly useful when the sample surface that is to be imaged is not too sensitive and/or easily damaged by the charged particle microscope.

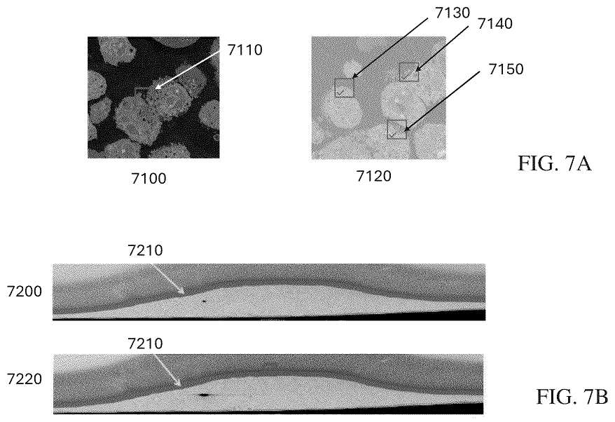

FIG. 7A illustrates an example of the above embodiments wherein similar areas of interest are identified in a subsequent sample surface. An indication of an area of interest 7110 is on a sample surface 7100 is provided. Following the steps recited in any of the above embodiments that may be performed by the system of FIGS. 4A and 4B according to the steps laid out in flow diagrams of FIGS. 5, 6a and 6b, similar areas of interest 7130, 7140 and 7150 are found on a subsequent sample surface 7120.

In some cases, a user may wish to track one or more areas of interest throughout subsequent sample surfaces given the initial one or more areas of interest. Example embodiments that may be performed by the system of FIGS. 4A and 4C according to the steps laid out in flow diagrams of FIGS. 5, 6a and 6b are discussed below. In one embodiment, to image surface N, the receiving module 4100 receives an image of surface N−1 4025 and the indication module 4200 receives an indication of an initial areas of interest as input 4050. The initial area of interest specifies (or identifies) a feature of interest. The image of surface N−1 4025 is the image of the surface before surface N which has already been imaged by one of the embodiments of this invention. The image of surface N−1 4025 is obtained by the receiving module 4100 as discussed in relation to FIG. 4A. The initial areas of interest 4050 are inputted into the area of interest module 4300, typically as a reference segmentation.

The ML model is arranged to track the initial area of interest 4050 through the sample surface images N−1, N, N+1 etc. It may be understood that such tracking is analogous to tracking an object through subsequent frames of a video. The ML model 4330 is arranged to generate an area of interest on the sample surface image N−1 corresponding to (or defining or including) the feature of interest 4055 of the initial area of interest. Typically, the output area of interest is in the form of a segmentation map (or mask) for the feature of interest.

The area of interest (or segmentation mask) is outputted to the charged particle microscope 110 and is used by the charged particle microscope 110 to estimate where the one or more areas of interest may be on surface N and perform autofunctions based on the estimated one or more areas of interest to image them. Said imaging comprises applying the one or more autofunctions based on at least one of the identified areas of interest and acquiring an image using the charged particle microscope 110 based on the output of the functions. It will be appreciated that the system 4000 may be arranged to apply the functions to the identified one or more areas of interest and configure the charged particle microscope 110 based on the parameters generated by said autofunctions. Similarly, once surface N is imaged, the image of surface N may be used to generate a segmentation mask to image surface N+1. This embodiment is particularly useful when the sample surface that is to be imaged is sensitive and may be damaged by the charged particle microscope.

In an alternative embodiment, to image surface N, surface N is initially imaged by the charged particle microscope 110 and inputted 4025 into the receiving module 4100. The image of surface N 4025 is then inputted into ML model to track the initial

area of interest 4050 through the image of surface N. The ML model 4330 is arranged to generate an area of interest on the sample surface image N corresponding to (or defining or including) the feature of interest 4055 of the initial area of interest. Typically, the output area of interest is in the form of a segmentation map (or mask) for the feature of interest.

The area of interest (or segmentation mask) is outputted to the charged particle microscope 110 and is used by the charged particle microscope 110 to re-image the surface N. Said reimaging comprises applying the one or more autofunctions based on at least the identified area of interest and acquiring an image of the surface N using the charged particle microscope 110 based on the output of the autofunctions. It will be appreciated that the system 4000 may be arranged to apply the autofunctions to the identified one or more areas of interest and configure the charged particle microscope 110 based on the parameters generated by said autofunctions. This method can be employed if the sample or sample surface isn't sensitive and therefore will not be damaged by an initial imaging.

FIG. 7B illustrates an example of the above embodiments wherein an initial area of interest is identified in a subsequent sample. An indication of an area of interest 7210 on a sample surface 7200 is provided. Following the steps recited in any of the above embodiments that may be performed by the system of FIGS. 4A and 4C according to the steps laid out in flow diagrams of FIGS. 5, 6A and 6B, the area of interest (7210) is identified on a subsequent sample surface 7220.

It will be appreciated that the methods described have been shown as individual steps carried out in a specific order. However, the skilled person will appreciate that these steps may be combined or carried out in a different order whilst still achieving the desired result.

It will be appreciated that embodiments of the invention may be implemented using a variety of different information processing systems. In particular, although the figures and the discussion thereof provide an exemplary computing system and methods, these are presented merely to provide a useful reference in discussing various aspects of the invention. Embodiments of the invention may be carried out on any suitable data processing device, such as a personal computer, laptop, personal digital assistant, mobile telephone, television, server computer, etc. Of course, the description of the systems and methods has been simplified for purposes of discussion, and they are just one of many different types of systems and methods that may be used for embodiments of the invention. It will be appreciated that the boundaries between logic blocks are merely illustrative and that alternative embodiments may merge logic blocks or elements, or may impose an alternate decomposition of functionality upon various logic blocks or elements.

It will be appreciated that the above-mentioned functionality may be implemented as one or more corresponding modules as hardware and/or software. For example, the above-mentioned functionality may be implemented as one or more software components for execution by a processor of the system. Alternatively, the above-mentioned functionality may be implemented as hardware, such as on one or more field-programmable-gate-arrays (FPGAs), and/or one or more application-specific-integrated-circuits (ASICs), and/or one or more digital-signal-processors (DSPs), and/or other hardware arrangements. Method steps implemented in flowcharts contained herein, or as described above, may each be implemented by corresponding respective modules; multiple method steps implemented in flowcharts contained herein, or as described above, may be implemented together by a single module.

It will be appreciated that, insofar as embodiments of the invention are implemented by a computer program, then a storage medium and a transmission medium carrying the computer program form aspects of the invention. The computer

program may have one or more program instructions, or program code, which, when executed by a computer carries out an embodiment of the invention. The term “program” as used herein, may be a sequence of instructions designed for execution on a computer system, and may include a subroutine, a function, a procedure, a module, an object method, an object implementation, an executable application, an applet, a servlet, source code, object code, a shared library, a dynamic linked library, and/or other sequences of instructions designed for execution on a computer system. The storage medium may be a magnetic disc (such as a hard drive or a floppy disc), an optical disc (such as a CD-ROM, a DVD-ROM or a BluRay disc), or a memory (such as a ROM, a RAM, EEPROM, EPROM, Flash memory or a portable/removable memory device), etc. The transmission medium may be a communications signal, a data broadcast, a communications link between two or more computers, etc.

1. A method for imaging a sample using a charged particle microscope, the method comprising:
acquiring an initial image of a surface of the sample using the charged particle microscope;
receiving an indication of one or more initial areas of interest for one or more auto-functions for the charged particle microscope;
acquiring a series of subsequent images of subsequent surfaces of the sample using the charged particle microscope,
wherein, for each subsequent image, acquiring said subsequent image comprises exposing the respective subsequent surface of the sample;
identifying, one or more areas of interest corresponding to the one or more initial areas of interest; and
imaging the respective subsequent surface wherein imaging the respective subsequent surface comprises applying the one or more auto-functions based on at least one of the identified areas of interest corresponding to the one or more initial areas of interest.

2. The method of claim 1 wherein identifying one or more surface areas of interest corresponding to the one or more initial areas of interest comprises:
identifying in a previous image one or more areas of interest corresponding to the one or more initial areas of interest: and
imaging the respective subsequent surface wherein imaging the respective subsequent surface comprises applying the one or more auto-functions based on at least one of the identified areas of interest of the previous image.

3. The method of claim 1 wherein identifying one or more surface areas of interest corresponding to the one or more initial areas of interest comprises:
imaging the surface;
identifying one or more areas of interest corresponding to the one or more initial areas of interest; and
imaging the surface wherein imaging the respective subsequent surface comprises applying the one or more auto-functions to at least one of the identified areas of interest.

4. The method of claim 1, wherein the method further comprises:
calculating similarity scores between the one or more initial areas of interest of the initial image and a plurality of sub-areas of the image of the respective subsequent surface of the sample; and
selecting one or more sub-areas as candidate areas of interest in the respective subsequent surface of the sample based on the respective similarity scores.

5. The method of claim 4 wherein the method further comprises:
computing reference encodings of the one or more initial areas of interest of the initial image;
computing encodings of the plurality of sub-areas of the image of the respective subsequent surface of the sample;
wherein the similarity score for each pair of initial areas of interest and sub-areas of interest is a similarity score between the respective encodings.

6. The method of claim 5 when dependent on claim 4 wherein the reference encoding is a deep embedding calculated by the trained machine learning algorithm, and the encodings of the plurality of sub-areas are deep embeddings of the plurality of sub-areas calculated by the trained machine learning model.

7. The method of claim 6 wherein the trained machine learning model is a vision transformer neural network.

8. The method of claim 4 wherein the similarity scores are cross correlations.

9. The method of claim 5 wherein the reference encodings and encodings of the sub-areas are respective image histograms and the similarity score is a Kullback-Leibler divergence between respective histograms.

10. The method of claim 5 wherein the reference encodings and encodings of the sub-areas are generated by Gabor filters.

11. The method of claim 4 wherein the similarity scores are cosine similarities.

12. The method of claim 4, further comprising:
selecting areas of interest from the candidate areas of interest based one or more selection criteria.

13. The method of claim 12, wherein:
the selection criteria comprises one or more of: a distance metric to the initial area of interest; exclusions areas on the surface; a distance metric to the centre of the field of view.

14. The method of claim 1 wherein
the step of identifying one or more areas of interest uses a trained machine learning model, wherein the one or more initial area of interest defines one or more features of interest,
and wherein said identifying comprises tracking, using the trained machine learning model, the one or more features of interest through the previous images of the series.

15. The method of claim 14 wherein the trained machine learning model is a Video Object Segmentation model.

16. The method of claim 14 wherein the trained machine learning model is arranged to segment each of the subsequent images using the initial area of interest as a reference segmentation of the feature of interest.

17. The method of claim 1 wherein receiving an indication of an initial area comprises:
receiving an annotation by a user indicating the initial area of interest.

18. The method of claim 1 wherein the sample for imaging may be a 3D biological sample prepared by cryogenic freezing, a 3D biological sample embedded in resin, a material science sample, or a semiconductor sample.

19. The method of claim 1 wherein exposing the respective subsequent surface of the sample comprises using focused ion or electron beam milling, a laser or a diamond blade to expose each subsequent surface.

20. The method of claim 1 wherein the autofunctions comprise one or more of a lens aligning function, a stigmator function, a focus function, a contrast/brightness function, a focus centering function, a stigmator centering function or a combination of previously listed basic autofunctions.

21.-22. (canceled)
